(19) United States
(12) Patent Application Publication
(10) Pub. No.: US 2004/0148766 A1
(43) Pub. Date: Aug. 5, 2004

(54) Multi-layer circuit board and method for manufacturing same

(76) Inventors: Jinichi Noguchi, Tokyo (JP); Shukichi Takii, Nagano (JP); Satoshi Ootsuki, Nagano (JP); Hiroyuki Makino, Kanagawa (JP); Susumu Sakuragi, Kanagawa (JP); Masaru Tanaka, Ehime (JP); Toshio Komiyatani, Tokyo (JP); Iji Onozuka, Tokyo (JP)

Correspondence Address: SMITH, GAMBRELL & RUSSELL, LLP, SUITE 3100, PROMENADE II, 1230 PEACHTREE STREET, N.E., ATLANTA, GA, 30309-3592, US

(21) Appl. No.: 10/758,371

(22) Filed: Jan. 15, 2004

(30) Foreign Application Priority Data
Jan. 17, 2003 (JP) 2003-009233

(51) Int. Cl. H05K 3/00; H05K 3/36

(52) U.S. Cl. 29/830; 29/829; 29/846

(57) ABSTRACT

The present invention provides the miniaturization and weight reduction of the multi-layer circuit board and improvement in the processability thereof. The multi-layer circuit board comprises a substrate 10, on at least one surface of a substrate 10, a first electrical conductive circuit (metal plating film 30) disposed on the substrate 10, an resin layer 20 disposed on the first electrical conductive circuit and a second electrical conductive circuit (metal plating film 30) disposed on the resin layer. The resin layer 20 is composed of a resin compound including benzocyclobutene resin, particulate inorganic filler and ultraviolet absorbent.

This application is based on Japanese patent application NO. 2003-009233, the content of which is incorporated hereinto by reference.

### BACKGROUND OF THE INVENTION

1. Field of the Invention

The present invention relates to a multi-layer circuit board, and a method for manufacturing same.

2. Description of the Related Art

Miniaturization and weight reduction of portable electronics devices such as portable personal computers, cellular phones or the like have been required in recent years. In such situation, miniaturization and weight reduction of multi-layer circuit boards included in the portable electronics devices, on which CPU, LSI or the like are mounted, are also required.

General multi-layer circuit board is manufactured by laminating a combination of boards and adhesive prepregs to form a multi-layer member, where the board includes insulating substrates and metal films such as copper films disposed on either or both of surfaces of insulating substrates. And heating and pressurizing of the multi-layer member is conducted to obtain the multi-layer circuit board. First, the metal films of respective boards are selectively etched to form a plurality of inner wiring layers. Then, prepreg is sandwiched with a plurality of inner wiring layers to form a multi-layer structure. Thereafter, the outermost metal film of the inner wiring layers is selectively etched to form an outermost layer. Subsequently, a surface treatment processing of the metal film is conducted to the outermost layer.

Then, via holes are formed in the outermost layer of thus formed inner wiring layer by the following manner. First, only the portions of the outermost metal, in which vias are formed, are selectively etched, or alternatively the entire surface thereof is etched, thereby removing the metal film of these portions. Thereafter, a drill processing is conducted by using a laser drill machine or the like at positions at which the metal film is etched off to form via holes. Subsequently, the bottoms and the sidewalls of the via holes are cleaned with permanganates and chemicals such as alkaline aqueous solution or the like. Also, a surface treatment is simultaneously conducted for the exposed outermost insulating layer.

Thereafter, underlying electrical conductive films are formed on the walls of the via holes by electroless copper plating or the like, and further metal plating films are formed thereon to electrically couple each of the layers.

Thereafter, metal films with resins are sequentially disposed on either one surface or on both surfaces of thus prepared inner wiring layers, and heating and pressurizing thereof are conducted. Subsequently, the process of forming the via holes are repeated to obtain the built-up type multi-layer circuit board having a desired number of layers that forms a laminated member.

In order to achieve the miniaturization and the weight reduction of the multi-layer circuit board having the above-mentioned structure, it is required that the thickness of the resin layer of the resin coated metal film should be thinner, the width of the wiring and/or the distance between the wirings should be minimized or the diameters of the via holes should be smaller and the thickness of the plating should be thinner.

In order to provide the thinner plating film, higher thermal resistance of the resin layer of the resin coated metal film is required for the purpose of preventing the generation of cracks in the plating film when thermal shock is experienced.

Further, faster operation of the above-mentioned electronics devices is also required, and the higher operation frequency for CPU is required. For this reason, it is necessary to achieve the faster rate of the signal propagation and the lower loss for the signal propagation. In order to achieve these requirements, the multi-layer circuit board is required to have lower relative dielectric constant and lower dielectric loss tangent.

In view of the above situation, JP-A-2000-21,872, for example, discloses benzocyclobutene resin as an exemplary resin compound.

Benzocyclobutene resin has considerably better dielectric properties and better thermal resistances, since curing reaction of benzocyclobutene resin does not create functional group having larger polarizability such as hydroxyl group.

On the other hand, the impedance controllability is required for the multi-layer circuit board adaptable to higher operation frequency, as well as the dielectric properties of the material thereof. In order to conduct the impedance control, it is necessary to control the width of the wiring, and is also necessary to control the thickness of the resin layer of the resin coated metal film to a constant thickness.

However, since benzocyclobutene resin has lower viscosity at an elevated temperature, the formation thereof is difficult when benzocyclobutene regin is employed for the resin coated metal film. That is, the flow of the resin layer of the resin coated metal film becomes excessively larger during the heating and pressurizing, and thus it is difficult to obtain uniform thickness of the resin layer.

In addition, since the circuit board materials such as benzocyclobutene resin generally have poor adhesiveness with the electrical conductive film, it has been impossible to form an uniform underlying electrical conductive film by employing such materials in the conventional chemical surface treatment or electroless plating, and also such materials have not been provide sufficient adhesiveness.

Further, since the circuit board materials having superior electrical properties such as benzocyclobutene resin are generally chemically stable and firm, the residual resin layer formed at the bottom of the via holes, remained after conducting the laser drilling, can not sufficiently be removed by the conventional wet cleaning with conventional chemicals. When the miniaturization of the circuit board is intended, palladium is generally employed for the catalyst in the processing of forming the underlying electrical conducting film by the conventional electroless plating. Since palladium generally remains on the circuit board surface after the formation process of the wiring when the cleaning with the chemicals is conducted, this residual palladium may cause an anomalous precipitation during the post processing thereof for forming the plating film, resulting in causing the deterioration of the insulation between the adjacent wirings. Also, when a chemical solution is employed for cleaning of the via holes, the chemical solution may permeate into the resin layer and/or between the electrical conducting films, thereby deteriorating the insulation and the adhesiveness between the vias and/or between the vias and the wirings. On the contrary, when the via holes are designed to be miniaturized to a level of micrometer order, the chemical solution may not sufficiently permeate into the via holes, causing insufficient cleaning thereof, and thus causing the poor electrical coupling.

### SUMMARY OF THE INVENTION

In view of the above situation, the present invention provides a solution to the above-mentioned problems, and it is an object of the present invention to provide a technology for providing the miniaturization and weight reduction of the multi-layer circuit board having the resin layer. It is another object of the present invention to provide a technology for improving the processability of the multi-layer circuit board including the resin layer. It is further object of the present invention to provide a technology for presenting the multi-layer circuit board having the resin layer having lower dielectric constant and lower dielectric loss tangent. It is yet another object of the present invention to provide a technology for adapting the multi-layer wiring for the use in the high frequency-operation.

According to the present invention, there is provided a multi-layer circuit board, comprising; a substrate; a first electrical conductive circuit disposed on at least one surface of the substrate; an resin layer disposed on said first electrical conductive circuit; and a second electrical conductive circuit disposed on said resin layer; wherein said resin layer includes a resin compound containing a benzocyclobutene resin, a particulate inorganic filler and an ultraviolet absorbent.

Having this configuration, electrical properties, thermal resistance, crack resistance and UV laser processability of the resin layer are improved. In particular, the processability may be improved by employing the particulate inorganic filler.

The multi-layer circuit board according to the present invention may have a configuration, in which the largest particle size of the inorganic filler may not be larger than 10 μm. Further, the multi-layer circuit board according to the present invention may have a configuration, in which average particle size of the inorganic filler is not larger than 2 μm.

Having this configuration, the processability for the substrate can be suitably maintained even in the case where the multi-layer circuit board having an ultra fine pattern thereof is manufactured, as well as favorably improving the crack resistance of the resin layer.

The multi-layer circuit board according to the present invention may have a configuration, in which a content of the inorganic filler is in a range from 5 parts by weight to 100 parts by weight relative to 100 parts by weight of the benzocyclobutene resin.

The multi-layer circuit board according to the present invention may have a configuration, in which the benzocyclobutene resin is composed of a monomer of a cyclobutene derivative represented by a general formula of IA, IB or IC:

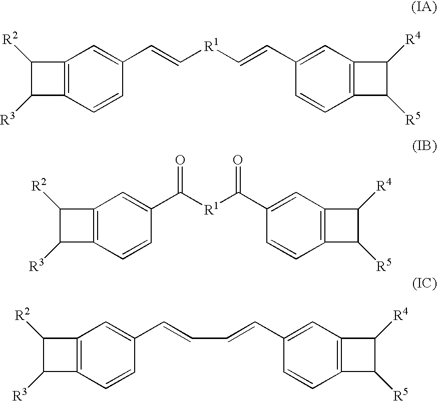

(where R₁ represents: halogen atom; alkyl group; haloalkyl group; aryl group; cycloalkyl group; hydroxyl group; alkoxy group; carboxylic group; alkoxy carbonyl group or acyl group, R₂, R₃, R₄ and R₅, which are same or different, represent: hydrogen atom; halogen atom; alkyl group; haloalkyl group; aryl group; cycloalkyl group; hydroxyl group; alkoxy group; carboxylic group; alkoxy carbonyl group or acyl group, wherein the R₂ and R₃ or the R₄ and R₅ are capable of coupling to form a cyclic structure).

The multi-layer circuit board according to the present invention may have a configuration, in which the ultraviolet absorbent contains benzophenones or benzotriazoles.

The multi-layer circuit board according to the present invention may have a configuration, in which a content of the ultraviolet absorbent is in a range from 0.01 part by weight to 5 parts by weight relative to 100 parts by weight of the benzocyclobutene resin.

The multi-layer circuit board according to the present invention may have a configuration, in which the relative dielectric constant of the resin layer is not more than 3.0.

The multi-layer circuit board according to the present invention may have a configuration, in which the dielectric loss tangent of the resin layer is not more than 0.005.

The multi-layer circuit board according to the present invention may have a configuration, in which the resin layer has an ultraviolet absorption region within a wavelength range from 200 nm to 400 nm.

According to the present invention, there is provided a method for manufacturing any one of the multi-layer circuit board having configurations described above, comprising: forming a via hole on the resin layer; and cleaning the via hole by conducting a plasma processing.

Having this configuration, residues remained in the via holes is removed, as well as providing the surface modification of the resin layer surface by the plasma processing, thereby improving the adhesiveness of the surface with an underlying electrical conductive film, which will be formed on the surface of the resin layer.

The method for manufacturing the multi-layer circuit board according to the present invention may have a configuration, in which the via holes are cleaned by a parallel plate processing in the step of cleaning the via holes.

The method for manufacturing the multi-layer circuit board according to the present invention may further comprises a step of conducting a plasma processing over the resin layer to form the underlying electrical conductive film on the surface of the resin layer. The method for manufacturing the multi-layer circuit board according to the present invention may further comprises a step of forming an wiring layer on the underlying electrical conductive film by an electroplating method.

The method for manufacturing the multi-layer circuit board according to the present invention may have a configuration, in which the wiring layer is formed by: forming a mask including an opening having a predetermined geometry on the underlying electrical conductive film; and depositing a plating film on an exposed portion of the underlying electrical conducting film that is exposed from the opening. In this case, the method for manufacturing the multi-layer circuit board according to the present invention may further comprise: removing the mask after forming the plating film; and removing a portion of the underlying electrical conducting film that becomes to be exposed after the step of removing the mask.

The method for manufacturing the multi-layer circuit board according to the present invention may have a configuration, in which the wiring is formed by depositing the plating film on the entire surface of the underlying electrical conducting film and selectively removing the plating film.

The method for manufacturing the multi-layer circuit board according to the present invention may have a configuration, in which a plasma processing can be employed for cleaning the resin layer, modifying the surface of the resin layer and forming the underlying electrical conducting film on the resin layer.

### BRIEF DESCRIPTION OF THE DRAWINGS

FIGS. 1A to 1D are cross sectional views of a multi-layer circuit board of an embodiment according to the present invention, showing the steps of the manufacturing process thereof.

FIGS. 2A to 2I are cross sectional views of a multi-layer circuit board of an embodiment according to the present invention, showing a procedure for forming via holes in an inner wiring layer.

FIGS. 3A to 3D are cross sectional views of a multi-layer circuit board of an embodiment according to the present invention, showing a procedure for forming a built-up type multi-layer circuit board after conducting the processing steps shown in FIGS. 2A to 2I.

FIG. 4A to 4D are cross sectional views of a multi-layer circuit board of an embodiment according to the present invention, showing a procedure for forming a built-up type multi-layer circuit board after conducting the processing steps shown in FIGS. 2A to 2I.

FIGS. 5A to 5H are cross sectional views of a multi-layer circuit board of an embodiment according to the present invention, showing another embodiment of process for forming a metal plating film.

### DETAILED DESCRIPTION OF THE INVENTION

Divinylsiloxane-bisbenzocyclobutene (commercially available from Dow Chemical), for example, may be employed for the benzocyclobutene resin according to the present invention. Benzocyclobutene resin is not limited thereto, and any resin may be employed as long as the resin contains cyclobutene bone structure. More preferably, benzocyclobutene resin may be a resin comprised of monomer represented by a general formula of one of the following IA, IB or IC:

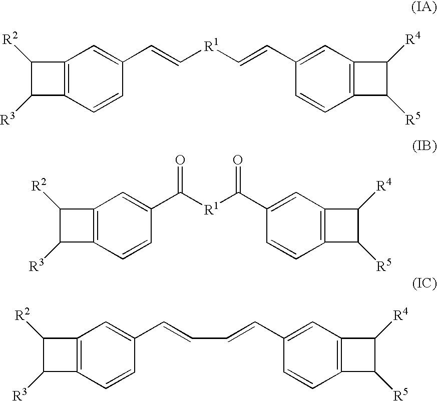

(where R₁ represents: halogen atom; alkyl group; haloalkyl group; aryl group; cycloalkyl group; hydroxyl group; alkoxy group; carboxylic group; alkoxy carbonyl group or acyl group, R₂, R₃, R₄ and R₅, which are same or different, represent: hydrogen atom; halogen atom; alkyl group; haloalkyl group; aryl group; cycloalkyl group; hydroxyl group; alkoxy group; carboxylic group; alkoxy carbonyl group or acyl group, wherein R₂ and R₃ or R₄ and R₅ are capable of coupling to form a cyclic structure).

Having this configuration, the resin having higher glass transition temperature is obtainable, thereby improving the resin properties of the cured resin. Having the resin compound composed of monomer of benzocyclobutene derivatives represented by the above-mentioned general formulas, the electrical properties of the resin layer can be improved. Since the benzocyclobutene derivatives do not generate any functional group having larger polarizability such as hydroxyl group or the like by the curing reaction thereof, the dielectric properties of the resin layer can be improved, and the lower water absorption of the resin layer can be maintained. Further, since the benzocyclobutene derivatives represented by the above-mentioned general formulas have rigid chemical structure, higher thermal resistance of the resin layer is also presented.

B-staged resins of benzocyclobutene derivatives represented by the above-mentioned formulas may also be preferably employed for the purpose of obtaining improved moldability and flowability. Typical B-staged resins of benzocyclobutene derivatives represented by the above-mentioned formulas employed for the present invention may be, for example, divinylsiloxane-bisbenzocyclobutene (B-staged resin. Weight-average molecular weight: 140,000, commercially available from Dow Chemical under the trade name of “cyclotene XUR”). The process of B-staging is normally conducted by the heating and fusing. Here, the B-staged benzocyclobutene resin is referred to as the resin having the number-average molecular weight of 3,000 to 1,000,000, for example. The number-average molecular weight of the resin can be determined by utilizing the gel permeation chromatography (GPC), for example.

Although the upper limit of the content of the benzocyclobutene resin in the resin compound may not particularly be limited, the content of the benzocyclobutene resin in the resin compound may preferably be not higher than 95 parts by weight relative to the whole materials composing the resin compound, and more preferably not higher than 90 parts by weight. Having the upper limit of the content of the benzocyclobutene resin in the resin compound in such range, the workability in the production process and the crack resistance of the product are sufficiently improved. Although the lower limit of the content of the benzocyclobutene resin in the resin compound may not also particularly be limited, the content of the benzocyclobutene resin in the resin compound may preferably be not lower than 20 parts by weight relative to the whole materials composing the resin compound, and more preferably not lower than 30 parts by weight. Having the lower limit of the content of the benzocyclobutene resin in the resin compound in such range, the dielectric properties such as relative dielectric constant and dielectric loss tangent can be improved.

The exemplary inorganic fillers available in the present invention may be, for example: oxides such as silica, fumed silica, alumina, zinc oxide, titanium oxide, aluminum borate, magnesia, beryllia or the like; silicates such as burnt clay or the like; carbonates such as calcium carbonate, hydro talcite or the like; hydroxides such as aluminum hydroxide, magnesium hydroxide or the like; sulfates or sulfites such as barium sulfate, calcium sulfite or the like; borates such as zinc borate or the like; or nitrides such as aluminum nitride, silicon nitride or the like. The present invention employs the particulate inorganic filler. The configuration of employing the particulate inorganic filler provides the improvements in the crack resistance and the laser processability of the resin compound. It is expected that a combination of such particulate inorganic filler and the aforementioned benzocyclobutene resin provides reducing the linear expansion coefficient of the resin compound and significantly improving the crack resistance thereof. The processability of the formation process of the via holes may be improved by forming the inorganic filler to the particulate form.

Although the upper limit of the particle size of the inorganic filler may not particularly be limited, the particle size thereof may preferably be not larger than 10 μm, and more preferably not larger than 6 μm, and further preferably not larger than 5 μm. In addition, the average particle size may preferably be not larger than 2 μm. Having the upper limit of the particle size of the inorganic filler in such range, the laser processability in the micro-processing can be improved. Although the lower limit of the particle size of the inorganic filler may not also particularly be limited, the particle size thereof may preferably be not smaller than 0.01 μm. In addition, the average particle size may preferably be not smaller than 0.1 μm. Having the lower limit of the particle size of the inorganic filler in such range, the crack resistance of the resin compound can be improved. The average particle size of the inorganic filler may be determined by, for example, employing a particle size distribution analyzer (LA-500, commercially available from HORIBA Co., Japan).

Although the upper limit of the relative dielectric constant of the inorganic filler may not particularly be limited, the relative dielectric constant of the inorganic filler may preferably be not higher than 20, and more preferably not higher than 10, and further preferably within a range from 1 to 8. Having the relative dielectric constant of the inorganic filler in such range, the multi-layer circuit board manufactured by employing the inorganic filler and the resin compound may have improved crack resistance without deteriorating the dielectric properties. Also, this configuration provides the adaptation of the multi-layer circuit board to the further progress in the faster signal propagation speed. Further, a combination of the inorganic filler having the relative dielectric constant of not higher than 20 and the aforementioned benzocyclobutene resin provides improving the crack resistance of the resin layer without deteriorating the dielectric properties of the resin layer.

The exemplary inorganic fillers having the relative dielectric constant of not higher than 20 may be, for example: oxides such as silica, alumina, magnesia, beryllia or the like; or sulfates such as barium sulfate or the like. Among these, it is preferable to have at least one or more selected from the group consisting of silica, alumina and barium sulfate. Having such inorganic filler provides that the advantages of lower relative dielectric constant and lower dielectric loss tangent of the benzocyclobutene can be maintained.

Although the upper limit of the content of the inorganic filler in the resin compound may not particularly be limited, the content of the inorganic filler in the resin compound may preferably be not higher than 100 parts by weight relative to 100 parts by weight of the above-mentioned benzocyclobutene resin, and more preferably not higher than 70 parts by weight. Having the upper limit of the content of the inorganic filler in the resin compound in such range, the reduction of the peel strength of the resin layer can be inhibited. Although the lower limit of the content of the inorganic filler in the resin compound may not also particularly be limited, the content of the inorganic filler in the resin compound may preferably be not lower than 5 parts by weight relative to 100 parts by weight of the above-mentioned benzocyclobutene resin, and more preferably not lower than 10 parts by weight. Having the lower limit of the content of the inorganic filler in the resin compound in such range, better crack resistance of the resin compound can be maintained.

Although the upper limit of the relative dielectric constant of the resin compound may not particularly be limited, the relative dielectric constant of the resin compound may preferably be not higher than 3.0, and more preferably not higher than 2.5. Having the upper limit of the relative dielectric constant of the resin compound in such range, the reduction of the topological consistency can be inhibited. Although the lower limit of the relative dielectric constant of the resin compound may not also particularly be limited, the relative dielectric constant of the resin compound may preferably be not lower than 1.5. Having the lower limit of the relative dielectric constant of the resin compound in such range presents better impedance controllability. Having the relative dielectric constant of the resin compound within such range provides the circuit board having better high frequency properties at a frequency not lower than 1 GHz.

Although the upper limit of the dielectric loss tangent of the resin compound may not particularly be limited, the dielectric loss tangent of the resin compound may preferably be not higher than 0.005, and more preferably not higher than 0.003. Having the upper limit of the dielectric loss tangent of the resin compound in such range, the increase of the signal loss can be inhibited, thereby providing a better operation of the mounted devices.

Also, the resin compound may preferably be formed to have an ultraviolet absorption region within the wavelength range from 200 nm to 400 nm. Having this configuration enables the formation of the micro via holes by utilizing the UV laser, thereby improving the laser processability. In order to present such characteristic ultraviolet absorption region to the resin compound, the resin compound may include an ultraviolet absorbent, which has an absorptivity of not less than 40% of UV in the wavelength range from 350 nm to 370 nm or in the wavelength range from 240 nm to 260 nm. Having this configuration, the productivity for the processing of the vias, particularly the UV laser processing of the vias, can be improved. Here, the term “having an absorptivity of not less than 40% of UV in the wavelength range” may include exhibiting an absorptivity of not less than 40% of UV in a limited part of the wavelength range or having an absorptivity of not less than 40% of UV throughout the entire wavelength range. Here, the term “absorptivity” represents the value obtained by the wavelength shape obtained from the measurement of the ultraviolet region-absorption by the sample solution contained in the sample cell having a sample optical path length of 1 cm via a photoelectron spectrophotometer, where the sample solution is prepared by mixing 5 mg of the ultraviolet absorbent into 100 ml of methanol solvent.

The exemplary ultraviolet absorbents may be:

benzophenones such as 4,4′-bisdiethylaminobenzophenone or the like;

benzotriazoles such as 2-benzyl-2-dimethylamino-1-(4-morpholinophenyl)-butanone-1,2-[5-(chloro-2′-hydroxy-3′tert-butyl-5′-methylphenyl)]-benzotriazole or the like;

1,1′,2,2′-tetrakis (4-glycidyl phenyl) ethane;

2,2-dimethoxy 1,2-diphenylethane-1-one;

2-methyl-1-[4-(methylthio)phenyl]-2-morpholinopropanone-1-benzoinisopropylether;

benzoin isobutylether;

benzyldimethylketal;

2-benzyl-2-dimethylamino 1-(4-morpholinophenyl)-butanone-1;

bis(2,4,6-trimethylbenzoil)-phenylphosphine oxide or the like.

Among these, benzophenones and benzotriazoles are preferable, and benzophenones such as 4,4′-bisdiethylaminobenzophenone or the like may more preferably be used. This considerably improves the UV laser processability of the resin compounds.

Although the upper limit of the content of the ultraviolet absorbent may not particularly be limited, the content of the ultraviolet absorbent may preferably be not higher than 5 parts by weight relative to 100 parts by weight of the benzocyclobutene resin, and more preferably not higher than 1.5 parts by weight. Having the upper limit of the content of the ultraviolet absorbent in such range, the reduction of the dielectric properties thereof can be inhibited. Although the lower limit of the content of the ultraviolet absorbent may not also particularly be limited, the content of the ultraviolet absorbent may preferably be not lower than 0.01 parts by weight relative to 100 parts by weight of the benzocyclobutene resin, and more preferably not lower than 0.1 parts by weight. Having the lower limit of the content of the ultraviolet absorbent in such range, the ultraviolet absorbing effect of the resin compound can sufficiently be exhibited, thereby improving the UV processability of the resin compound. The presence of the available ultraviolet absorbing region of the resin compound may be evaluated by using an ultraviolet spectrophotometer (commercially available from SHIMADZU, Japan, under the trade name of “UV-260”).

(Formation of Inner Wiring Layer)

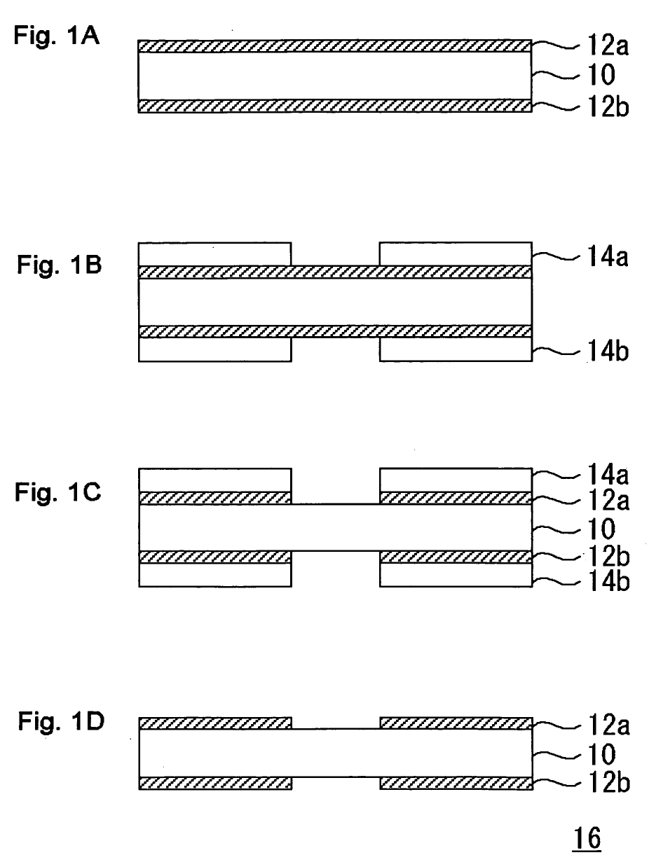

FIGS. 1A to 1D are cross sectional views of a multi-layer circuit board, showing the steps of the manufacturing process.

First, a substrate 10 having a metal film 12a on a front side (top side in the figure) and a metal film 12b on a backside (bottom side in the figure) is prepared (FIG. 1A). The substrate 10 is composed of an insulating material, and more specifically the substrate may be composed of, for example, epoxy resin, glass base-epoxy resin laminated plate, glass base-polyimide resin laminated plate, glass base-PTFE (Teflon^{TR}) laminated plate, glass base-bismaleimide triazine resin laminated plate, glass base-cyanate resin laminated plate, glass base-polyphenylene ether resin laminated plate, polyester resins, ceramics, resin-impregnated ceramics or the like. Copper film may be employed for the metal films 12a and 12b. Although the present embodiment employs the configuration that the metal films 12a and 12b are formed on both sides of the substrate 10, another configuration, in which a metal film is formed on either one surface of the surface, may be employed.

Subsequently, a patterned protective films 14a and 14b having predetermined patterns are formed on the metal films 12a and 12b, respectively (FIG. 1B). The protective films 14a and 14b are the etching resist. Thereafter, the metal films 12a and 12b are selectively etched through the protective films 14a and 14b, respectively, to provide a predetermined pattern to the metal films 12a and 12b (FIG. 1C). Subsequently, the protective films 14a and 14b are removed to form an inner wiring layer 16 (FIG. 1D).

Although thus formed inner wiring layer 16 alone may be used, a plurality of the similarly formed inner wiring layers 16 may also be laminated by laminating the inner wiring layers 16 via the prepreg disposed therebetween after conducting the chemical treatment of the surface of the inner wiring layers 16, and heating and pressurizing thereof to form a multi-layered inner wiring layers. When the inner wiring layers are laminated to form the multi-layered inner wiring layers, each of a plurality of the inner wiring layers 16 may be electrically coupled through via holes (not shown).

(Formation of the Built-Up Type Multi-Layer Wirings)

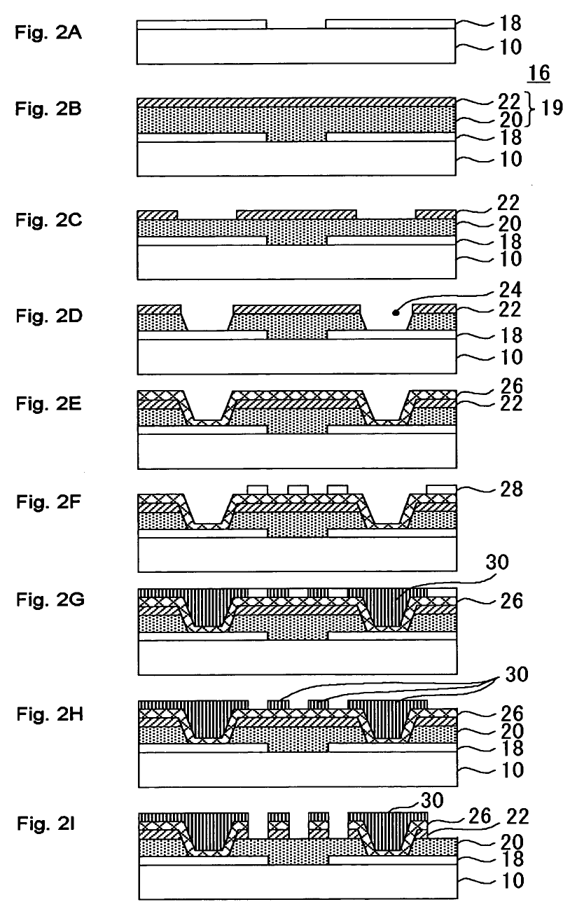

FIGS. 2A to 2I show the procedures for forming the via holes in the inner wiring layer 16 having a metal film 18 only on one side of the substrate 10. The metal film 18 is patterned to have a predetermined pattern, similarly as in the description in reference to FIGS. 1A to 1D (FIG. 2A).

A resin coated metal film 19 (comprising an resin layer 20 and a metal film 22) is formed on the metal film 18 of the thus obtained inner wiring layer 16 (FIG. 2B). Copper film may also be employed for the metal film 22 and the metal film 18, similarly as in the case of the metal films 12a and 12b.

The resin layer 20 according to the present embodiment contains a base resin, a particulate inorganic filler and an ultraviolet absorbent or the like. The particulate inorganic filler is introduced into the resin layer 20 to maintain the lower relative dielectric constant of the resin layer 20 as well as improving the crack resistance thereof. The base resin employed in the present embodiment is the aforementioned benzocyclobutene resin.

Further, although the resin layer 20 of the resin coated metal film 19 mainly contains the benzocyclobutene resin as the base resin, other components such as other resin, curing accelerator, cross linker, elastomer, coupling agent, fire retardant agent or the like may be added, unless otherwise incompatible with the object of the present invention.

Further, the insulating compound composing the resin layer 20 may be employed in various manners and forms. When the resin coated metal film 19 is obtained by applying the insulating compound onto the metal film 22, the form of the varnish containing the insulating compound dissolved in a solvent may generally be employed in view of obtaining better applicability. Although the solvent may preferably be a good solvent exhibiting better solubility for the compositions for forming the resin layer, poor solvent may also be employed unless otherwise adversely affecting thereto. The typical good solvent may be toluene, xylene, mesitylene, cyclohexanone or the like.

The varnish containing the insulating compound according to the embodiment of the present invention dissolved in a solvent is applied onto the metal film 22 and the coated metal film is dried at a temperature of 80 to 200 degree C. to form the resin coated metal film 19. The application of the varnish to the metal film 22 may be carried out by employing a common coater. Thus obtained resin coated metal film 19 is disposed on the metal film 18 of the inner wiring layer 16, and the heating and pressurizing are conducted thereto, to form a laminated member as shown in FIG. 2B. The heating temperature may not particularly be limited, and may preferably be 140 to 240 degree C. The pressurizing pressure may not particularly be limited, and may preferably be 10 to 40 kg/cm². Although the resin coated metal film 19 is formed only on one side (upper side in the figure) of the inner wiring layer 16, the metal films with resins 19 may be formed on both sides of the inner wiring layer 16.

Subsequently, the positions on the metal film 22 where via holes are to be formed are selectively etched to partially expose the resin layer 20 (FIG. 2C). Then, via holes 24 are formed on the exposed portions of the resin layer 20 via the suitable method such as UV laser method (FIG. 2D).

Subsequently, the surface of the resin layer 20 and the bottom surface and the side surfaces of the via holes 24 are cleaned by a plasma processing. The cleaning by the plasma processing may be carried out under the conditions of, for example, gas atmosphere at a pressure of several mTorr to several Torr and with an RF voltage source of several kHz to several tens MHz. The gases employed in this embodiment may be a reactive gas such as oxygen or the like, or an inert gas such as nitrogen, argon or the like, for example. The gas components are activated by the plasma and the activated gas species chemically reacts, physically reacted by the mutual bombardment of the gas species themselves (bombarding), or the combination thereof to clean the residues in the via holes 24 off and/or the surface stains of lower molecular off, depending upon the pressure and the type of the gases. The cleaning may be carried out by the parallel plate method.

As described above, the cleaning with the plasma can achieve the removal of the persistent residual matters of the insulating resins which can not otherwise completely removed by the wet cleaning with a chemical solution. Since this cleaning does not employ any chemical solution, the permeation of the chemical solution or the introduction of ions into the interfaces of the wiring of the inner wiring layer 16 and the resin layer 20 can be avoided. Further, the surface of the resin layer 20 exposed by the plasma can also be modified by the plasma process, thereby improving the adhesiveness with the electrically conductive film, which will be formed later.

After the above-mentioned cleaning process, an underlying electrical conductive film 26 is formed on the entire surface of the resin layer 20 by the plasma processing (FIG. 2E). The underlying electrical conductive film 26 may be formed by, for example, ion plating. In this case, the underlying electrical conductive film 26 having a thickness of about several hundred nm can be formed on the surface of the resin layer 20 by discharging with the direct current voltage in an atmosphere of an inert gas at a pressure from 10⁻² Torr to 10⁻⁵ Torr to ionize a metal such as copper for forming the underlying electrical conductive film 26.

Also, bias voltage of several tens V to several hundred V may be applied to the surface of the resin layer 20 during the formation process of the underlying electrical conductive film 26. This causes striking effect of the ions thereto, thereby improving the adhesiveness between the underlying electrical conductive film 26 and the resin layer 20, in comparison with the case of free of application of the bias voltage.

Also, the underlying electrical conductive film 26 may be formed by sputtering, vacuum deposition, or physical vapor deposition (PVD) utilizing ion beams, or chemical vapor deposition (CVD) utilizing reactive gases.

Subsequently, a protective layer for the plating process 28 is formed on the underlying electrical conductive film 26 by, for example, a photosensitive resist (FIG. 2F). The protective layer for the plating process 28 is exposed to light through the patterned mask having a predetermined pattern and developed. This provides selectively removing the portions of the protective layer for the plating process 28 where plating layers are to be formed.

Next, metal plating layers 30 of a metal such as copper or the like are formed on the underlying electrical conductive film 26 (FIG. 2G). The metal plating film 30 may be formed by an electrolytic plating method. This provides forming the metal plating film 30 (having a thickness of, for example, 10 to 25 μm) on the regions where the protective layer for the plating process 28 has been selectively removed. The metal plating film 30 may be formed under a condition of an electrical current density of 0.1 to 5.0 A/dm². Having the electrical current density within such range prevents the deterioration of the quality of the skin film. Thereafter, the protective layer for the plating process 28 is stripped and removed (FIG. 2H).

Also, the plating solution for the use in the electrolytic plating may include an additive. Additives for via-filling (for example, an additive commercially available from Okuno Pharmaceuticals Co., Ltd., under the trade name of “TOP LUCINA a” series, or an additive commercially available from Ebara-Udylite Co., Ltd., under the trade name of “Cu-Brite VFII” series) may be employed to precipitating the metal plating such as copper preferentially in the via holes 24, thereby evenly filling the via holes 24 with the metal. When the metal plating film 30 comprises copper, the plating solution may include, for example: copper sulfate pentahydrate (CuSo₄.5H₂O: 60 to 230 g/liter); sulfuric acid (H₂SO₄: 15 to 210 g/liter); and chlorine ion (Cl⁻: 20 to 70 mg/liter). Further, the plating solution may additionally include the above-mentioned additive for via-filling: (for TOP LUCINA a series, “aM”: 2 to 10 ml/liter (preferably 4.5 ml/liter); “a1”: 2 to 5 ml/liter (preferably, 3 ml/liter); and “a2”: 0.7 to 1.2 ml/liter (preferably 1 mi/liter), for Cu-Brite VFII series, “VFII-A”: 20 to30 ml/liter (preferably 20 ml/liter); and “VFII-B”: 0.3 to 1 ml/liter (preferably 1 ml/liter)). Thus, the via holes 24 can be evenly filled with the metal film to provide that an upper via can be formed directly above the lower layer via when a built-up layer having a plurality of layers is formed, thereby presenting advantages of increasing the density of the wirings, reducing the wiring length, increasing the current capacity and improving the heat dissipation.

Subsequently, the underlying electrical conductive film 26 exposing on the top surface and the metal film 22 below thereof are removed via a soft etching process to expose the resin layer 20 in regions other than the regions where the metal plating films 30 are formed (FIG. 2I). The soft etching process may be carried out by, for example, conducting an etching process using an etchant solution containing sulfuric acid and hydrogen peroxide. The formation of the first electrical conductive film is completed by the above described process.

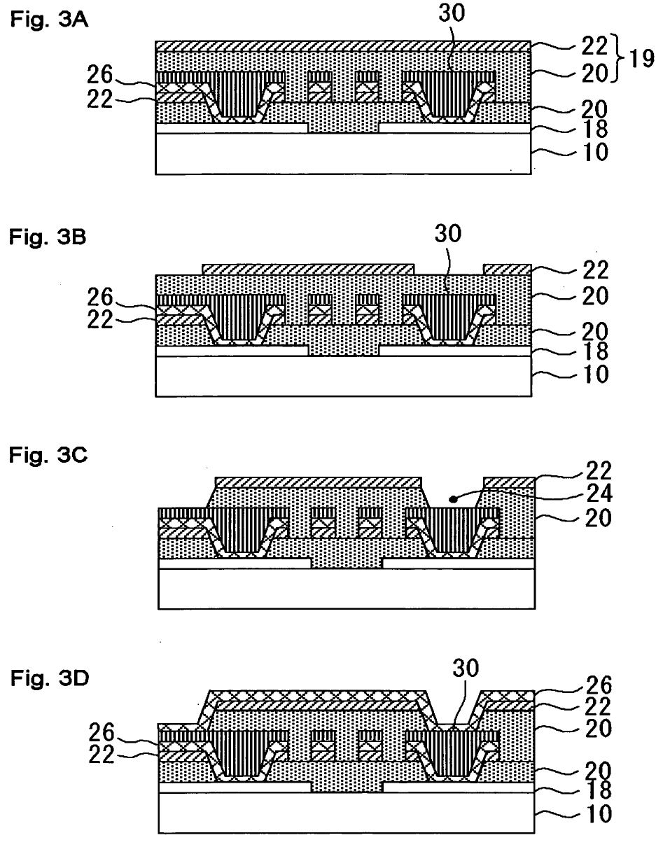

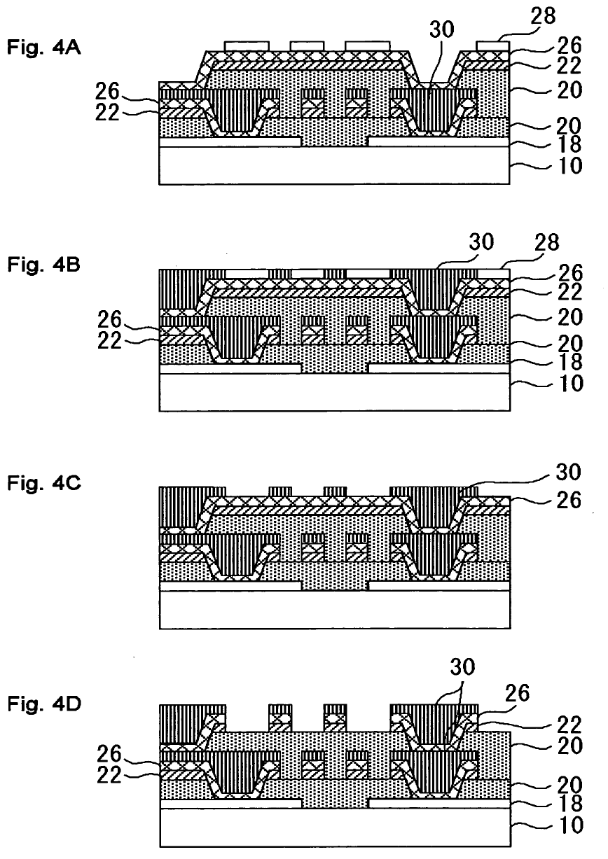

FIGS. 3A to 3D and FIGS. 4A to 4D show the procedures for forming the built-up type multi-layer circuit board after the processing steps represented by FIGS. 2A to 2I.

As formerly descried in reference to FIG. 2I, after removing the underlying electrical conductive film 26 and the metal film 22 below thereof, a resin coated metal film 19 (comprising an resin layer 20 and a metal film 22) is formed on the entire surface of the metal plating film 30, similarly as described in the method represented by FIG. 2B (FIG. 3A). Subsequently, the positions on the metal film 22 where via holes are to be formed are selectively etched to partially expose the resin layer 20 (FIG. 3B). Thereafter, via holes 24 are formed on the exposed portions of the resin layer 20 (FIG. 3C). After conducting the cleaning process with the plasma and the surface treatment of the resin layer 20, an underlying electrical conductive film 26 is formed on the entire surface of the resin layer 20 (FIG. 3D). Subsequently, a protective layer for the plating process 28 having a predetermined geometry is formed on the underlying electrical conductive film 26 (FIG. 4A). Then, a metal plating film 30 is formed on the underlying electrical conductive film 26 (FIG. 4B). Thereafter, the protective layer for the plating process 28 is stripped and removed (FIG. 4C), and then the underlying electrical conductive film 26 exposing on the top surface and the metal film 22 below thereof are removed to expose a region of the resin layer 20 other than the regions on which the metal plating films 30 are formed (FIG. 4D).

The above described processing steps shown in FIGS. 3A to 3D and FIGS. 4A to 4D may be repeated for a desired number of times to form the desired number of the multi-layer circuit boards.

### EXAMPLES

The present invention will be described in reference to the examples and the comparative examples, and it should be emphasized that the present invention is not particularly limited thereto.

### Example 1

i) Preparation of the Resin Layer Varnish

A base resin of 80 parts by weight of divinylsiloxane-bisbenzocyclobutene (B-staged resin. Weight-average molecular weight is 140,000, commercially available from Dow Chemical under the trade name of “cyclotene XUR”), and an inorganic filler of 20 parts by weight of an inorganic filler of silica (commercially available from Admatechs Co., Ltd., Japan, under the trade name of “SO-25H”, relative dielectric constant is not higher than 20) and an ultraviolet absorbent of 1 parts by weight of 4,4′-bisdiethylaminobenzophenone (commercially available from Mitsubishi Chemical Co., Ltd., Japan, under the trade name of “EAB”) were dissolved into mesitylene and the compositions of the resin layer varnish was adjusted so that the contents of the involatile matters were 50 parts by weight.

(ii) Application to the Metal (Copper) Film

The above-mentioned resin layer varnish was applied onto a copper film (thickness: 0.018 mm, commercially available from Furukawa Circuit Foil Co., Ltd., Japan) to a thickness of 0.07 mm, and the applied film was dried in the drying furnace set at 150 degree C. for 10 minutes and subsequently in the drying furnace set at 170 degree C. for 10 minutes to prepare a resin coated metal film having a thickness of the resin layer of 0.07 mm.

(iii) Manufacture of the Multi-Layer Circuit Board

A double side-copper bonded laminated plate having copper films of 35 μm-thick on both surfaces and having a pattern of different line widths and different line pitches was prepared as a core, and the aforementioned copper films with resins were adhered onto the both sides of the laminated plate by heating and pressurizing at 170 degree C. for 1 hour and at 200 degree C. for 2 hours to thermally cure the resin, thereby forming the multi-layer circuit board.

### Comparative Example 1

No inorganic filer was employed in this Comparative Example. A base resin of 100 parts by weight of divinylsiloxane-bisbenzocyclobutene (B-staged resin. Weight-average molecular weight: 140,000, commercially available from Dow Chemical under the trade name of “cyclotene XUR”) and an ultraviolet absorbent of 1 parts by weight of 4,4′-bisdiethylaminobenzophenone (commercially available from Mitsubishi Chemical Co., Ltd., Japan, under the trade name of “EAB”) were dissolved into mesitylene and the compositions of the resin layer varnish was adjusted so that the contents of the involatile matters were 50 parts by weight. The multi-layer circuit board of the Comparative Example was prepared by using this varnish via a similar method as in the manufacture of the above-mentioned Example.

The multi-layer circuit boards obtained in the above-mentioned Example and Comparative Example were evaluated as follows. The evaluation items are described below with the details of the contents of the evaluations. The obtained results are shown in Table-1.

a) UV Processability (Via Processability)

Via drilling with UV at the wavelength of 355 nm was conducted, and the drilled vias were observed with an optical microscope. The sign indicates the following condition.

(double circle): no delamination was generated.

b) Relative Dielectric Constant

The relative dielectric constant was measured by employing a porosity method at a frequency of 1 MHz (A-state).

c) Crack Resistance

Crack resistance was measured by conducting a liquid phase thermal shock test (−65 degree C. and 125 degree C./100 cycles). The generation of the cracks was evaluated by a visual observation. The signs indicate the following conditions.

(double circle): no crack was generated.

(triangle): cracks were partially generated and the product was not in the condition of the practical use.

d) Moldability

The Moldability was evaluated via the generation of the void after the manufacture of the multi-layer circuit board. The generation of the void was evaluated by a visual observation. The sign indicates the following condition.

(double circle): no void was generated.

e) Thickness Accuracy

The thickness accuracy was evaluated by observing the cross section of the multi-layer printed board by using an optical microscope. The sign indicates the following condition.

(double circle): variation of the thickness was less than 15 μm.

TABLE 1

| | | Comparative |
|---|---|---|
| | Example | Example |
| base resin (benzocyclobutene resin) | 80 parts | 100 parts |
| inorganic filler | 20 parts | — |
| UV absorbent (benzophenones) | 1.0 | 1.0 |
| UV processability | ⊚ | ⊚ |
| | (double | (double |
| | circle) | circle) |
| relative dielectric constant | 2.8 | 2.7 |
| crack resistance | ⊚ | Δ |
| | (double | (triangle) |
| | circle) | |
| moldability | ⊚ | ⊚ |
| | (double | (double |
| | circle) | circle) |
| thickness accuracy | ⊚ | ⊚ |
| | (double | (double |
| | circle) | circle) |

AS shown in Table-1, improved crack resistance was obtained in the Example in comparison with the Comparative Example. In addition, the UV processability was also better in the Example, and thus it is seen that the conditions employed in the Example enabled the micro via processing. Further, the result of the Example shows that the addition of the inorganic filler did not cause the unwanted increase of the relative dielectric constant, and presented better results in the moldability and the thickness accuracy.

The present invention has been described in detail in reference to the preferred Embodiment and the Example. It should be understood by a person having ordinary skills in the art that the disclosure of the preferred Embodiment and the Example are presented for the purpose of the illustration only, and these subject matters and/or the processing steps thereof themselves or the combination thereof may be modified without departing from the scope and/or the spirit of the invention. The followings are the illustrations of such modifications.

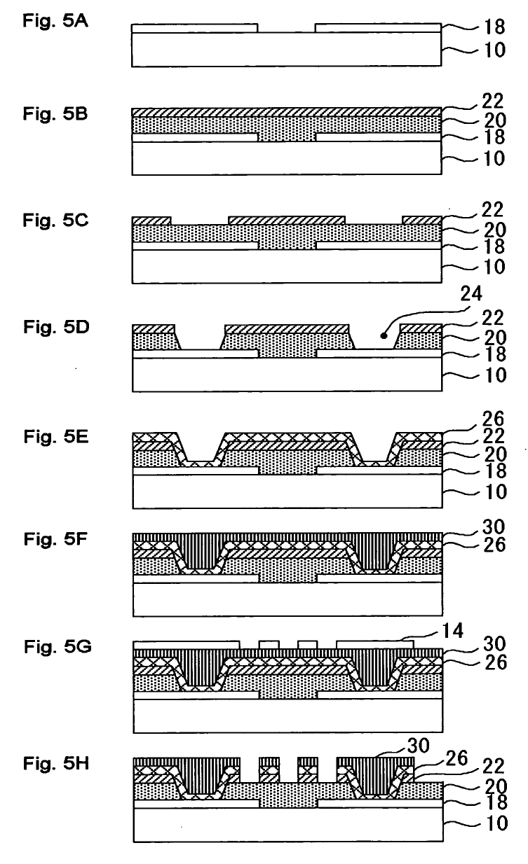

In the preferred embodiment of the present invention, as described in reference to FIG. 2F and FIG. 2G for example, the metal plating film 30 was selectively formed after forming the protective film for the plating process 28. Alternatively, the metal plating film 30 may also be formed by another procedures represented by FIGS. 5A to 5H. In the alternative procedures, the processing steps represented by FIGS. 5A to 5E are similar to that represented by FIGS. 2A to 2E, and thus the details thereof will not be described. Here, after the formation of the underlying electrical conductive film 26 (FIG. 5E), the metal plating film 30 is formed on the entire surface of the underlying electrical conductive film 26 (FIG. 5F). Subsequently, a protective film 14 having a predetermined geometry is formed on the metal plating film 30 with, for example, an etching resist (FIG. 5G). Then, the metal plating film 30 is selectively etched via the protective film 14 to form a predetermined geometry (FIG. 5H). In this occasion, portions of the underlying electrical conductive film 26 and the metal film 22 in a region where no protective film 14 is formed thereon may selectively be removed.

Although the description of the preferred embodiment indicates that the metal film 22 is selectively etched (see FIG. 2C or FIG. 3B), the entire metal film 22 may be etched off to expose the resin layer 20.

Although the description of the preferred embodiment indicates that the resin coated metal film 19 including the resin layer 20 is formed and the resin coated metal film 19 is heated and pressurized to form the inner wiring layer 16, the lamination of the resin layer 20 and the metal film 22 into the inner wiring layer 16 may alternatively be carried out by heating and pressurizing of a resin sheet or a prepreg, or by printing of or coating with an insulating resin.

Although the description of the preferred embodiment illustrates that copper is employed for the underlying electrical conductive film 26 and the metal plating film 30, other metals than copper such as gold, silver, nickel, chromium or the like may be employed and the combination of different metals may also be used. For example, nickel is sputtered to form a film having a thickness of 0.5 μm and a copper plating layer may further be formed thereon to have a copper thickness of 10 to 25 μm. In such case, it is advantageous that the soft etching process utilizing a chemical that is capable of preferentially solve nickel may be conducted to form the wiring layer without reducing the copper layer.

What is claimed is:

1. A multi-layer circuit board, comprising;
a substrate;
a first electrical conductive circuit disposed on at least one surface of said substrate;
an resin layer disposed on said first electrical conductive circuit; and
a second electrical conductive circuit disposed on said resin layer;
wherein said resin layer includes a resin compound containing a benzocyclobutene resin, a particulate inorganic filler and an ultraviolet absorbent.

2. The multi-layer circuit board according to claim 1, wherein the largest particle size of said inorganic filler is not larger than 10 μm.

3. The multi-layer circuit board according to claim 1, wherein average particle size of said inorganic filler is not larger than 2 μm.

4. The multi-layer circuit board according to claim 2, wherein average particle size of said inorganic filler is not larger than 2 μm.

5. The multi-layer circuit board according to claim 1, wherein a content of said inorganic filler is in a range from 5 parts by weight to 100 parts by weight relative to 100 parts by weight of said benzocyclobutene resin.

6. The multi-layer circuit board according to claim 2, wherein a content of said inorganic filler is in a range from 5 parts by weight to 100 parts by weight relative to 100 parts by weight of said benzocyclobutene resin.

7. The multi-layer circuit board according to claim 3, wherein a content of said inorganic filler is in a range from 5 parts by weight to 100 parts by weight relative to 100 parts by weight of said benzocyclobutene resin.

8. The multi-layer circuit board according to claim 4, wherein a content of said inorganic filler is in a range from 5 parts by weight to 100 parts by weight relative to 100 parts by weight of said benzocyclobutene resin.

9. The multi-layer circuit board according to claim 1, wherein said benzocyclobutene resin is composed by a monomer of a benzocyclobutene derivative having a general formula of IA, IB or IC: 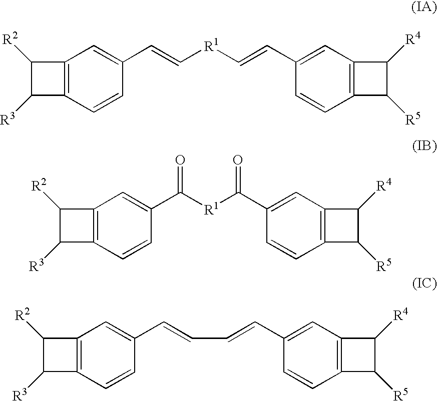
(where R₁ represents: halogen atom; alkyl group; haloalkyl group; aryl group; cycloalkyl group; hydroxyl group; alkoxy group; carboxylic group; alkoxy carbonyl group or acyl group, R₂, R₃, R₄ and R₅, which are same or different, represent: hydrogen atom; halogen atom; alkyl group; haloalkyl group; aryl group; cycloalkyl group; hydroxyl group; alkoxy group; carboxylic group; alkoxy carbonyl group or acyl group, wherein said R₂ and R₃ or said R₄ and R₅ are capable of coupling to form a cyclic structure).

10. The multi-layer circuit board according to claim 1, wherein said ultraviolet absorbent contains benzophenones or benzotriazoles.

11. The multi-layer circuit board according to claim 1, wherein a content of said ultraviolet absorbent is in a range from 0.01 part by weight to 5 parts by weight relative to 100 parts by weight of the benzocyclobutene resin.

12. The multi-layer circuit board according to claim 1, wherein the relative dielectric constant of said resin layer is not more than 3.0.

13. The multi-layer circuit board according to claim 1, wherein the dielectric loss tangent of said resin layer is not more than 0.005.

14. The multi-layer circuit board according to claim 1, wherein said resin layer has an ultraviolet absorption region within a wavelength range from 200 nm to 400 nm.

15. A method for manufacturing said multi-layer circuit board according to claim 1, comprising:
forming a via hole on said resin layer; and
cleaning said via hole by conducting a plasma processing.
